(19) United States
(12) Patent Application Publication
(10) Pub. No.: US 2026/0305296 A1
(43) Pub. Date: Oct. 1, 2026

(54) SEMICONDUCTOR DEVICE INCLUDING VIA

(71) Applicant: Samsung Electronics Co., Ltd., Suwon-si (KR)

(72) Inventors: Min Chul Ahn, Suwon-si (KR); Yeong Gil KIM, Suwon-si (KR); Jong Min Baek, Suwon-si (KR); Hoon Seok Seo, Suwon-si (KR); Deok Young Jung, Suwon-si (KR)

(73) Assignee: Samsung Electronics Co., Ltd., Suwon-si (KR)

(21) Appl. No.: 19/393,384

(22) Filed: Nov. 18, 2025

(30) Foreign Application Priority Data
Mar. 25, 2025 (KR) 10-2025-0037673

(51) Int. Cl. H01L 23/522; H01L 21/768

(52) U.S. Cl. CPC H10W 20/42; H10W 20/033; H10W 20/056; H10W 20/074; H10W 20/076

(57) ABSTRACT

A semiconductor device includes a first interlayer insulating layer, a lower wiring layer disposed in the first interlayer insulating layer, a connection trench formed on an upper surface of the lower wiring layer within the first interlayer insulating layer, the connection trench extending in a vertical direction from the upper surface of the lower wiring layer to an upper surface of the first interlayer insulating layer, an etching stop layer disposed along the upper surface of the first interlayer insulating layer, and sidewalls and a bottom surface of the connection trench, a second interlayer insulating layer disposed on an upper surface of the etching stop layer, a via disposed on the upper surface of the lower wiring layer within the second interlayer insulating layer, at least a portion of the via disposed within the connection trench, the via spaced apart from the sidewalls of the connection trench in a first horizontal direction and in a second horizontal direction perpendicular to the first horizontal direction, and a spacer surrounding sidewalls of the via, and at least a portion of the spacer disposed within the connection trench.

### CROSS-REFERENCE TO RELATED APPLICATIONS

This present application claims priority to and the benefit under 35 U.S.C. § 119(a)-(d) of Korean Patent Application No. 10-2025-0037673, filed on Mar. 25, 2025, in the Korean Intellectual Property Office, the entire disclosure of which is incorporated herein by reference.

### FIELD

The present disclosure relates to a semiconductor device including via.

### BACKGROUND

With the advancement of electronic technology, the down-scaling of semiconductor devices has rapidly progressed in recent years, resulting in increasing demands for higher integration and lower power consumption of semiconductor chips. As the spacing between circuit elements such as wiring patterns continues to decrease, reliability issues have emerged between the wiring patterns.

### SUMMARY

An objective of the present disclosure is to provide a semiconductor device that improves electrical reliability between a via and an adjacent wiring layer.

The aspects of the present disclosure are not limited to those mentioned over, and another aspect which is not mentioned may be clearly understood by those skilled in the art from the description below.

According to some embodiments of the present disclosure, there is provided a semiconductor device, comprising a first interlayer insulating layer, a lower wiring layer disposed in the first interlayer insulating layer, a connection trench formed on an upper surface of the lower wiring layer within the first interlayer insulating layer, the connection trench extending in a vertical direction from the upper surface of the lower wiring layer to an upper surface of the first interlayer insulating layer, an etching stop layer disposed along the upper surface of the first interlayer insulating layer, and sidewalls and a bottom surface of the connection trench, a second interlayer insulating layer disposed on an upper surface of the etching stop layer, a via disposed on the upper surface of the lower wiring layer within the second interlayer insulating layer, at least a portion of the via disposed within the connection trench, the via spaced apart from the sidewalls of the connection trench in a first horizontal direction and in a second horizontal direction perpendicular to the first horizontal direction, and a spacer surrounding sidewalls of the via, and at least a portion of the spacer disposed within the connection trench.

According to some embodiments of the present disclosure, there is provided a semiconductor device, comprising a first interlayer insulating layer, a lower wiring layer disposed in the first interlayer insulating layer, a connection trench formed on an upper surface of the lower wiring layer within the first interlayer insulating layer, the connection trench extending in a vertical direction from the upper surface of the lower wiring layer to an upper surface of the first interlayer insulating layer, a second interlayer insulating layer disposed on the upper surface of the first interlayer insulating layer, and at least a portion of the second interlayer insulating layer disposed within the connection trench, a via disposed on the upper surface of the lower wiring layer within the second interlayer insulating layer, at least a portion of the via disposed within the connection trench, the via spaced apart from sidewalls of the connection trench in a first horizontal direction and in a second horizontal direction perpendicular to the first horizontal direction, an upper wiring layer being in contact with an upper surface of the via within the second interlayer insulating layer, and a spacer surrounding each of sidewalls of the via and sidewalls of the upper wiring layer, at least a portion of the spacer disposed within the connection trench.

According to some embodiments of the present disclosure, there is provided a semiconductor device, comprising a first interlayer insulating layer, a lower wiring layer disposed in the first interlayer insulating layer, a connection trench formed on an upper surface of the lower wiring layer within the first interlayer insulating layer, the connection trench extending in a vertical direction from the upper surface of the lower wiring layer to an upper surface of the first interlayer insulating layer, an etching stop layer disposed along the upper surface of the first interlayer insulating layer, and sidewalls and a bottom surface of the connection trench, a second interlayer insulating layer disposed on an upper surface of the etching stop layer, at least a portion of the second interlayer insulating layer disposed within the connection trench, a via disposed on the upper surface of the lower wiring layer within the second interlayer insulating layer, at least a portion of the via disposed within the connection trench, the via spaced apart from the sidewalls of the connection trench in a first horizontal direction and in a second horizontal direction perpendicular to the first horizontal direction, an upper wiring layer being in contact with an upper surface of the via within the second interlayer insulating layer, and having a width of a bottom surface in the second horizontal direction greater than a width of the upper surface of the via in the second horizontal direction, and a spacer surrounding each of sidewalls of the via and sidewalls of the upper wiring layer, at least a portion of the spacer disposed within the connection trench, an uppermost surface of the spacer formed on the same plane as an upper surface of the upper wiring layer, a lowermost surface of the spacer being in contact with the upper surface of the lower wiring layer, wherein at least a portion of the etching stop layer is disposed between the sidewall of the connection trench in the first horizontal direction and the spacer, and wherein at least a portion of the etching stop layer is disposed between the sidewall of the connection trench in the second horizontal direction and the spacer.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a schematic layout diagram for explaining a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIGS. 4 to 17 are intermediate stage diagrams for explaining a method for fabricating a semiconductor device according to some embodiments of the present disclosure;

FIG. 18 is a cross-sectional view for explaining a semiconductor device according to embodiments of the present disclosure;

FIGS. 19 to 23 are intermediate stage diagrams for explaining a method for fabricating a semiconductor device according to some embodiments of the present disclosure;

FIG. 24 is a cross-sectional view for explaining a semiconductor device according to some embodiments of the present disclosure; and

FIGS. 25 and 26 are cross-sectional views for explaining a semiconductor device according to embodiments of the present disclosure.

FIGS. 27 to 34 are intermediate stage diagrams for explaining a method for fabricating a semiconductor device according to some embodiments of the present disclosure.

### DETAILED DESCRIPTION

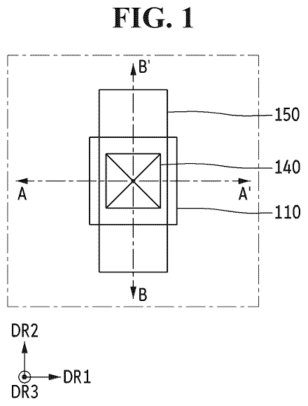

Hereinafter, a semiconductor device according to some embodiments of the present disclosure will be described with reference to FIGS. 1 to 3.

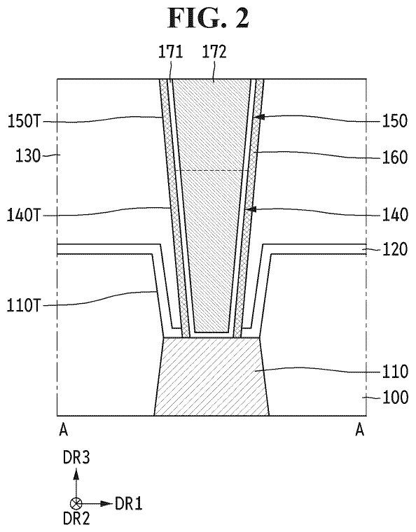

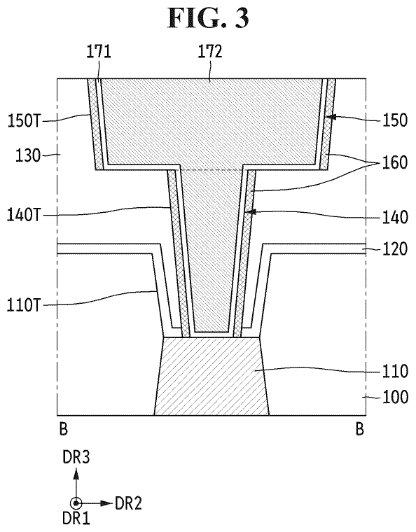

FIG. 1 is a schematic layout for explaining a semiconductor device according to some embodiments of the present disclosure. FIG. 2 is a cross-sectional view taken along line A-A′ of FIG. 1. FIG. 3 is a cross-sectional view taken along line B-B′ of FIG. 1.

Referring to FIGS. 1 to 3, a semiconductor device according to some embodiments of the present disclosure may include a first interlayer insulating layer 100, a lower wiring layer 110, a connection trench 110T, an etching stop layer 120, a second interlayer insulating layer 130, a via trench 140T, a via 140, an upper wiring trench 150T, an upper wiring layer 150, a spacer 160, a wiring barrier layer 171, and a wiring filling layer 172.

The first interlayer insulating layer 100 may include, for example, at least one of silicon oxide (SiO₂), SiCOH, silicon oxycarbide (SiOC), silicon oxynitride (SiON), and low-k dielectric materials. Low-k dielectric materials include, for example, Tetraethyl orthosilicate (TEOS), Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoxySiloxane (DADBS), TriMethylSilil Phosphate (TMSP), PolyTetraFluoroEthylene (PTFE), TOSZ(Tonen SilaZen), FSG (Fluoride Silicate Glass), polyimide nanofoams such as polypropylene oxide, CDO (Carbon Doped silicon Oxide), OSG (Organo Silicate Glass), SiLK, Amorphous Fluorinated Carbon, silica aerogels, silica xerogels, mesoporous silica, or combinations thereof. However, the present disclosure is not limited thereto.

Hereinafter, a first horizontal direction DR1 and a second horizontal direction DR2 may be defined as directions parallel to the upper surface of the first interlayer insulating layer 100. The second horizontal direction DR2 may be defined as a direction perpendicular to the first horizontal direction DR1. A vertical direction DR3 may be defined as a direction perpendicular to both the first horizontal direction DR1 and the second horizontal direction DR2. In other words, the vertical direction DR3 may be defined as a direction perpendicular to the upper surface of the first interlayer insulating layer 100.

A lower wiring layer 110 may be disposed within the first interlayer insulating layer 100. For example, an upper surface of the lower wiring layer 110 may be formed lower than an upper surface of the first interlayer insulating layer 100. In FIGS. 2 and 3, the bottom surface of the lower wiring layer 110 is shown to be formed on the same plane as the bottom surface of the first interlayer insulating layer 100, but the present disclosure is not limited thereto. For example, the lower wiring layer 110 may be formed as a single layer. However, the present disclosure is not limited thereto. In some other embodiments, the lower wiring layer 110 may be formed as a multilayer structure.

For instance, a width of the upper surface of the lower wiring layer 110 in the first horizontal direction DR1 may be smaller than a width of the bottom surface of the lower wiring layer 110 in the first horizontal direction DR1. Additionally, a width of the upper surface of the lower wiring layer 110 in the second horizontal direction DR2 may be smaller than a width of the bottom surface of the lower wiring layer 110 in the second horizontal direction DR2 However, the present disclosure is not limited thereto. In some other embodiments, the width of the upper surface of the lower wiring layer 110 in the first horizontal direction DR1 may be greater than the width of the bottom surface of the lower wiring layer in the first horizontal direction DR1. Likewise, the width of the upper surface of the lower wiring layer 110 in the second horizontal direction DR2 may also be greater than the width of the bottom surface of the lower wiring layer 110 in the second horizontal direction DR2.

In FIG. 1, the planar shape of the lower wiring layer 110 is shown to have the same or similar width in the first and second horizontal directions DR1, DR2. However, the present disclosure is not limited thereto. In some other embodiments, the lower wiring layer 110 may be formed to extend in the first horizontal direction DR1 or the second horizontal direction DR2. The lower wiring layer 110 may include a conductive material.

The connection trench 110T may be formed on the upper surface of the lower wiring layer 110 within the first interlayer insulating layer 100. The connection trench 110T may extend in the vertical direction DR3 from the upper surface of the lower wiring layer 110 to the upper surface of the first interlayer insulating layer 100. For example, the width of the upper surface of the connection trench 110T in the first horizontal direction DR1 may be greater than the width of the bottom surface of the connection trench 110T in the first horizontal direction DR1. Additionally, the width of the upper surface of the connection trench 110T in the second horizontal direction DR2 may be greater than the width of the bottom surface of the connection trench 110T in the second horizontal direction DR2.

In FIG. 2, the width of the bottom surface of the connection trench 110T in the first horizontal direction DR1 is shown to be the same as the width of the upper surface of the lower wiring layer 110 in the first horizontal direction DR1, but the present disclosure is not limited thereto. Also, in FIG. 3, the width of the bottom surface of the connection trench 110T in the second horizontal direction DR2 is shown to be the same as the width of the upper surface of the lower wiring layer 110 in the second horizontal direction DR2, but the present disclosure is not limited thereto.

The etching stop layer 120 may be arranged along the upper surface of the first interlayer insulating layer 100, as well as along the sidewalls and bottom surface of the connection trench 110T. That is, at least a portion of the etching stop layer 120 may be disposed within the connection trench 110T. The etching stop layer 120 may be in contact with the upper surface of the lower wiring layer 110 and the first interlayer insulating layer 100 within the connection trench 110T. Additionally, the etching stop layer 120 may be in contact with the upper surface of the first interlayer insulating layer 100. For example, the etching stop layer 120 may be formed conformally. For example, the etching stop layer 120 may be formed as a single layer. However, the present disclosure is not limited thereto. In some other embodiments, the etching stop layer 120 may be formed as a multilayer structure.

For example, the etching stop layer 120 may include one or more of aluminum nitride (AlN), aluminum oxide (Al₂O₃), hafnium oxide (HfO), zirconium oxide (ZrO), hafnium nitride (HfN), zirconium nitride (ZrN), yttrium oxide (Y₂O₃), yttrium nitride (YN), silicon oxide (SiO₂), silicon nitride (SiN), silicon oxynitride (SiON), silicon oxycarbide (SiOC), silicon carbide (SiC), and low-k dielectric materials.

The second interlayer insulating layer 130 may be disposed on the upper surface of the etching stop layer 120. The second interlayer insulating layer 130 may be in contact with the upper surface of the etching stop layer 120. That is, the etching stop layer 120 may be disposed between the first interlayer insulating layer 100 and the second interlayer insulating layer 130. For example, at least a portion of the second interlayer insulating layer 130 may be disposed within the connection trench 110T. For example, the second interlayer insulating layer 130 may include at least one of silicon oxide (SiO₂), SiCOH, silicon oxycarbide (SiOC), silicon oxynitride (SiON), and low-k dielectric materials.

A via trench 140T may be formed on the upper surface of the lower wiring layer 110 within the second interlayer insulating layer 130. The via trench 140T may penetrate the second interlayer insulating layer 130 in the vertical direction DR3 to extend to the upper surface of the lower wiring layer 110. For example, at least a portion of the via trench 140T may be formed within the connection trench 110T. For example, the via trench 140T may overlap the upper surface of the lower wiring layer 110 in the vertical direction DR3.

For example, both sidewalls of the via trench 140T in the first horizontal direction DR1 may be spaced apart from both sidewalls of the connection trench 110T in the first horizontal direction DR1. Additionally, both sidewalls of the via trench 140T in the second horizontal direction DR2 may be spaced apart from both sidewalls of the connection trench 110T in the second horizontal direction DR2. However, the present disclosure is not limited thereto. For example, the width of the via trench 140T in the first horizontal direction DR1 may continuously decrease as it approaches the upper surface of the lower wiring layer 110. Likewise, the width of the via trench 140T in the second horizontal direction DR2 may continuously decrease as it approaches the upper surface of the lower wiring layer 110.

The upper wiring trench 150T may be formed over the via trench 140T within the second interlayer insulating layer 130. For example, the upper wiring trench 150T may be formed to recess from the upper surface of the second interlayer insulating layer 130 toward the inside of the second interlayer insulating layer 130. For example, the upper wiring trench 150T may extend in the second horizontal direction DR2. For instance, the upper wiring trench 150T may overlap the via trench 140T in the vertical direction DR3. For example, the sidewall of the upper wiring trench 150T in the first horizontal direction DR1 may have a continuous sloped profile with the sidewall of the via trench 140T in the first horizontal direction DR1.

For example, at least a portion of the bottom surface of the upper wiring trench 150T may be defined by the second interlayer insulating layer 130. For example, the width of the upper wiring trench 150T in the second horizontal direction DR2 may be greater than the width of the via trench 140T in the second horizontal direction DR2. For instance, the width of the upper wiring trench 150T in the first horizontal direction DR1 may continuously decrease as it approaches the via trench 140T. Likewise, the width of the upper wiring trench 150T in the second horizontal direction DR2 may continuously decrease as it approaches the via trench 140T.

A spacer 160 may be disposed along the sidewall of the via trench 140T. Additionally, the spacer 160 may be disposed along the sidewall of the upper wiring trench 150T. For example, the spacer 160 may be formed conformally. For example, at least a portion of the spacer 160 may be disposed within the connection trench 110T. For example, the lowermost surface of the spacer 160 may be in contact with the upper surface of the lower wiring layer 110. For example, the uppermost surface of the spacer 160 may be formed on the same plane as the upper surface of the second interlayer insulating layer 130. For example, on the upper surface of the lower wiring layer 110, the sidewall of the spacer 160 may be in contact with the etching stop layer 120.

For instance, the spacer 160 disposed on the sidewall of the upper wiring trench 150T in the first horizontal direction DR1 may be arranged continuously with the spacer 160 disposed on the sidewall of the via trench 140T in the first horizontal direction DR1. For example, on the sidewall of the via trench 140T in the second horizontal direction DR2, the spacer 160 may not be arranged along the bottom surface of the upper wiring trench 150T. That is, the spacer 160 disposed on the sidewall of the upper wiring trench 150T in the second horizontal direction DR2 may be arranged discontinuously with the spacer disposed on the sidewall of the via trench 140T in the second horizontal direction DR2.

For example, the spacer 160 may be spaced apart from the sidewall of the connection trench 110T in the first horizontal direction DR1. Additionally, the spacer 160 may be spaced apart from the sidewall of the connection trench 110T in the second horizontal direction DR2. At least a portion of the etching stop layer 120 may be disposed between the sidewall of the connection trench 110T in the first horizontal direction DR1 and the spacer 160. Additionally, at least a portion of the etching stop layer 120 may be disposed between the sidewall of the connection trench 110T in the second horizontal direction DR2 and the spacer 160. For example, within the connection trench 110T, at least a portion of the second interlayer insulating layer 130 may be disposed between the etching stop layer 120 and the spacer 160. That is, within the connection trench 110T, the etching stop layer 120 may be disposed between the first interlayer insulating layer 100 and the spacer 160.

The spacer 160 may include an insulating material. For example, the material of the spacer 160 may be different from that of the etching stop layer 120. However, the present disclosure is not limited thereto. For instance, the spacer 160 may include at least one of silicon nitride (SiN), silicon oxynitride (SiON), silicon oxide (SiO₂), silicon carbonitride (SiCN), silicon oxycarbonitride (SiOCN), silicon boron nitride (SiBN), silicon oxyboron nitride (SiOBN), silicon oxycarbide (SiOC), titanium oxide (TiO₂), and combinations thereof. However, the present disclosure is not limited thereto.

A via 140 may be disposed within the via trench 140T. For example, the via 140 may be disposed between spacers 160 within the via trench 140T. In other words, the via 140 may be disposed on the upper surface of the lower wiring layer 110 within the second interlayer insulating layer 130. The via 140 may extend in the vertical direction DR3 from the upper surface of the lower wiring layer 110. For example, at least a portion of the via 140 may be disposed within the connection trench 110T. For example, the via 140 may overlap the upper surface of the lower wiring layer 110 in the vertical direction DR3. For example, the bottom surface of the via 140 may be in contact with the upper surface of the lower wiring layer 110. The via 140 may be electrically connected to the lower wiring layer 110. For example, the via (140) may be spaced apart from the sidewall of the connection trench 110T in the first horizontal direction DR1. Additionally, the via 140 may be spaced apart from the sidewall of the connection trench 110T in the second horizontal direction DR2.

For example, both sidewalls of the via 140 in the first horizontal direction DR1 may be in contact with the spacer 160. Additionally, both sidewalls of the via 140 in the second horizontal direction DR2 may be in contact with the spacer 160. That is, the spacer 160 may surround the sidewalls of the via 140. For example, within the connection trench 110T, the via 140 may not be in contact with an etching stop layer 120. That is, within the connection trench 110T, the via 140 may be spaced apart from the etching stop layer 120 in both the first and second horizontal directions DR1, DR2. For example, the width of the via 140 in the first horizontal direction DR1 may continuously decrease as it approaches the upper surface of the lower wiring layer 110. Also, the width of the via 140 in the second horizontal direction DR2 may continuously decrease as it approaches the upper surface of the lower wiring layer 110. The via 140 may include a conductive material.

An upper wiring layer 150 may be disposed within the upper wiring trench 150T. For example, the upper wiring layer 150 may be disposed between spacers 160 within the upper wiring trench 150T. That is, the upper wiring layer 150 may be disposed on the upper surface of the via 140 within the second interlayer insulating layer 130. For example, the upper wiring layer 150 may extend in the second horizontal direction DR2. For example, the upper wiring layer 150 may overlap the upper surface of the via 140 in the vertical direction DR3. For example, a portion of the bottom surface of the upper wiring layer 150 may be in contact with the upper surface of the via 140. The upper wiring layer 150 may be electrically connected to the via 140. For example, on the sidewall of the via trench 140T in the second horizontal direction DR2, at least a portion of the bottom surface of the upper wiring layer 150 may be in contact with the second interlayer insulating layer 130.

For example, the sidewall of the upper wiring layer 150 in the first horizontal direction DR1 may have a continuous sloped profile with the sidewall of the via 140 in the first horizontal direction DR1. For example, the width of the bottom surface of the upper wiring layer 150 in the first horizontal direction DR1 may be the same as the width of the upper surface of the via 140 in the first horizontal direction DR1. However, the present disclosure is not limited thereto. For example, the width of the bottom surface of the upper wiring layer 150 in the second horizontal direction DR2 may be greater than the width of the upper surface of the via 140 in the second horizontal direction DR2. As another example, the width of the upper wiring layer 150 in the first horizontal direction DR1 may continuously decrease as it approaches the upper surface of the via 140. In addition, the width of the upper wiring layer 150 in the second horizontal direction DR2 may also continuously decrease as it approaches the upper surface of the via 140.

For example, both sidewalls of the upper wiring layer 150 in the first horizontal direction DR1 may be in contact with spacer 160. Likewise, both sidewalls of the upper wiring layer 150 in the second horizontal direction DR2 may be in contact with spacer 160. That is, the spacer 160 may surround the sidewalls of the upper wiring layer 150. For example, the upper surface of the upper wiring layer 150 may be formed on the same plane as the upper surface of the second interlayer insulating layer 130. For example, the upper surface of the upper wiring layer 150 may be formed on the same plane as the uppermost surface of the spacer 160. The upper wiring layer 150 may include a conductive material.

For example, each of the via 140 and the upper wiring layer 150 may include a wiring barrier layer 171 and a wiring filling layer 172. The wiring barrier layer 171 may form the bottom surface and sidewalls of the via 140 and a portion of the bottom surface and sidewalls of the upper wiring layer 150. For example, the wiring barrier layer 171 may not be disposed between the upper surface of the via 140 and the bottom surface of the upper wiring layer 150. For example, on the sidewalls of the via 140 in the second horizontal direction DR2, the wiring barrier layer 171 may be in contact with the second interlayer insulating layer 130. For example, the wiring barrier layer 171 may include at least one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), or a combination thereof. However, the present disclosure is not limited thereto.

The wiring filling layer 172 may fill the space between the wiring barrier layers 171 of the via 140. Additionally, the wiring filling layer 172 may fill the space between the wiring barrier layers 171 of the upper wiring layer 150. For example, the upper surface of the wiring filling layer 172 of the via 140 may be in contact with the bottom surface of the wiring filling layer 172 of the upper wiring layer 150. That is, the wiring filling layer 172 of the via 140 and the wiring filling layer 172 of the upper wiring layer 150 may be formed integrally. For example, the wiring filling layer 172 may include one or more of copper (Cu), carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), aluminum (Al), zirconium (Zr), tungsten (W), ruthenium (Ru), iridium (Ir), or rhodium (Rh). However, the present disclosure is not limited thereto.

Hereinafter, a method for fabricating a semiconductor device according to several embodiments of the present disclosure will be described with reference to FIGS. 2 to 17.

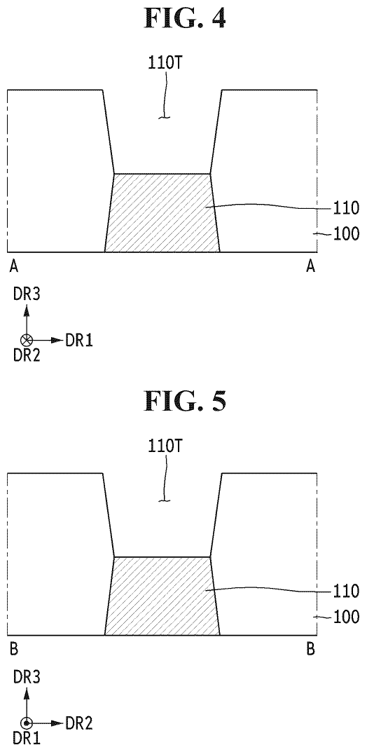

FIGS. 4 to 17 are intermediate stage diagrams for explaining the method for fabricating a semiconductor device according to several embodiments of the present disclosure.

Referring to FIGS. 4 and 5, a first interlayer insulating layer in which each of the lower wiring layer 110 and the connection trench 110T is formed may be provided. The connection trench 110T may be formed on the upper surface of the lower wiring layer 110 within the first interlayer insulating layer 100. The connection trench 110T may extend in the vertical direction DR3 from the upper surface of the lower wiring layer 110 to the upper surface of the first interlayer insulating layer 100. The connection trench 110T may expose the upper surface of the lower wiring layer 110.

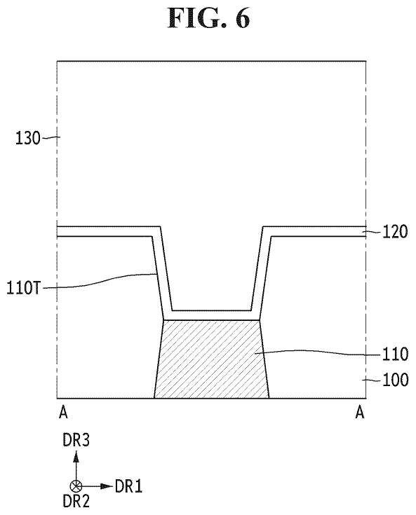

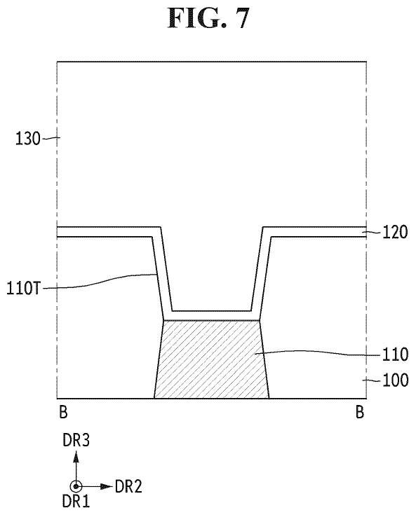

Referring to FIGS. 6 and 7, the etching stop layer 120 may be formed along the upper surface of the first interlayer insulating layer 100 and along the sidewalls and bottom surface of the connection trench 110T. At least a portion of the etching stop layer 120 may be formed within the connection trench 110T. Then, the second interlayer insulating layer 130 may be formed on the upper surface of the etching stop layer 120. At least a portion of the second interlayer insulating layer 130 may be formed within the connection trench 110T.

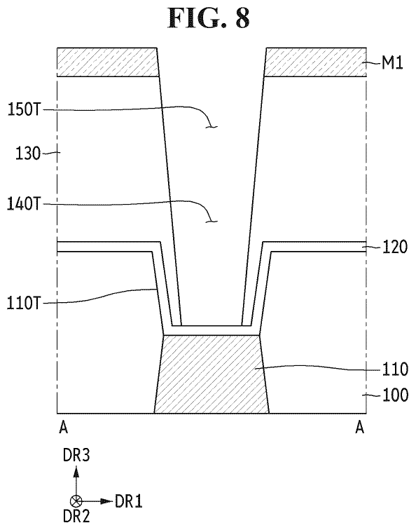

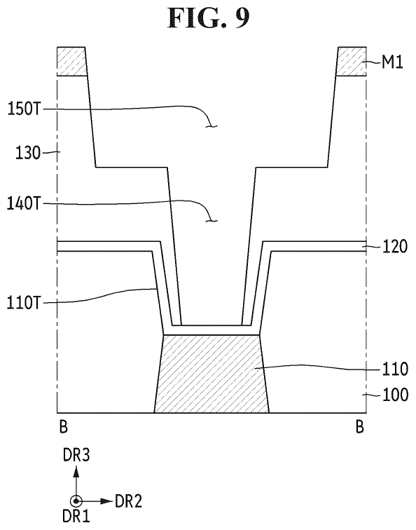

Referring to FIGS. 8 and 9, the via trench 140T and an upper wiring trench 150T may be formed using a mask pattern M1 formed on the upper surface of the second interlayer insulating layer 130 as a mask. For example, the via trench 140T and the upper wiring trench 150T may be formed through the same fabrication process. However, the present disclosure is not limited thereto.

For example, the via trench 140T may penetrate the second interlayer insulating layer 130 in the vertical direction DR3 on the upper surface of the lower wiring layer 110. The etching stop layer 120 may be exposed through the bottom surface of the via trench 140T. For example, the upper wiring trench 150T may be formed over the via trench 140T. The upper wiring trench 150T may extend in the second horizontal direction DR2. For instance, the width of the upper wiring trench 150T in the second horizontal direction DR2 may be greater than the width of the via trench 140T in the second horizontal direction DR2.

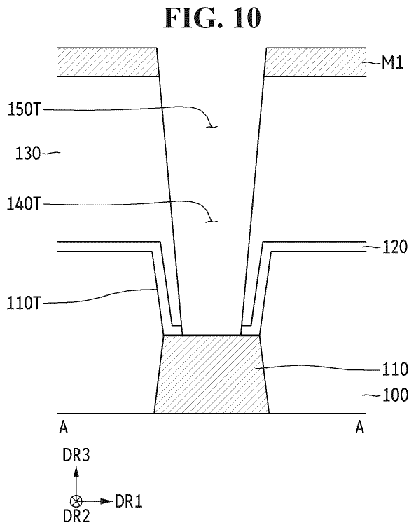

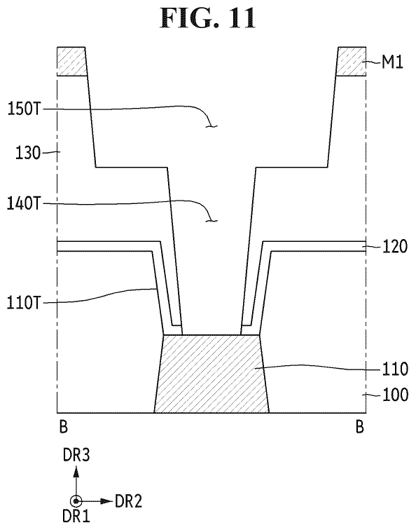

Referring to FIGS. 10 and 11, the etching stop layer 120 exposed through the bottom surface of the via trench 140T may be etched. As a result, the upper surface of the lower wiring layer 110 may be exposed through the bottom surface of the via trench 140T.

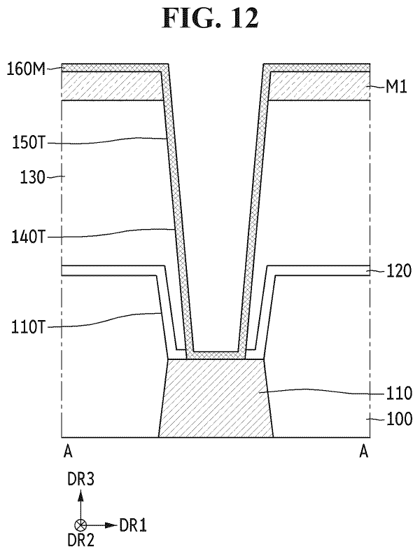

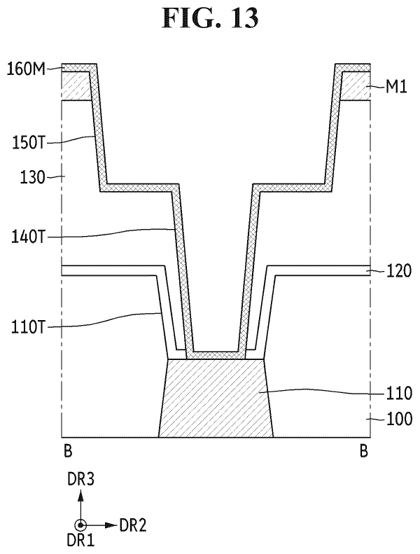

Referring to FIGS. 12 and 13, a spacer material layer 160M may be formed on the sidewalls and bottom surface of the via trench 140T, the sidewalls and bottom surface of the upper wiring trench 150T, and the exposed surface of the mask pattern M1. For example, the spacer material layer 160M may be conformally formed. The spacer material layer 160M may include the same material as the spacers 160 shown in FIGS. 2 and 3.

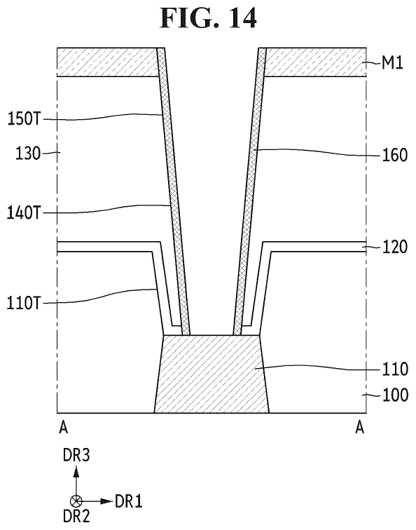

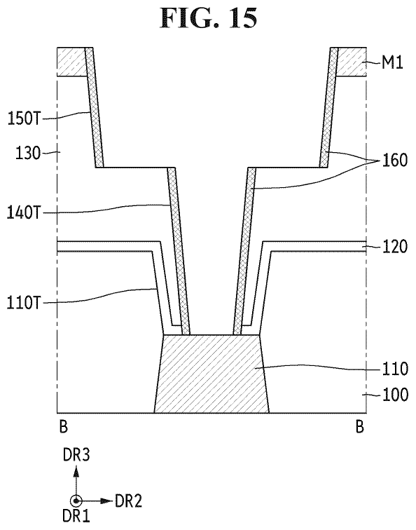

Referring to FIGS. 14 and 15, for example, an etch back process may be performed to partially etch the spacer material layer 160M (see FIGS. 12 and 13). For example, portions of the spacer material layer 160M (see FIGS. 12 and 13) formed on each of the bottom surface of the via trench 140T, the bottom surface of the upper wiring trench 150T, and the upper surface of the mask pattern M1 may be etched. After this etching process is completed, the upper surface of the lower wiring layer 110 may be exposed through the bottom surface of the via trench 140T, and the second interlayer insulating layer 130 may be exposed through the bottom surface of the upper wiring trench 150T.

Additionally, after such an etching process is completed, the remaining portions of the spacer material layer 160M (see FIGS. 12 and 13) may be defined as spacers 160. For example, the spacers 160 may be formed along the sidewalls of the via trench 140T. The spacers 160 may also be formed along the sidewalls of the upper wiring trench 150T. For example, the lowermost surfaces of the spacers 160 may be in contact with the upper surface of the lower wiring layer 110.

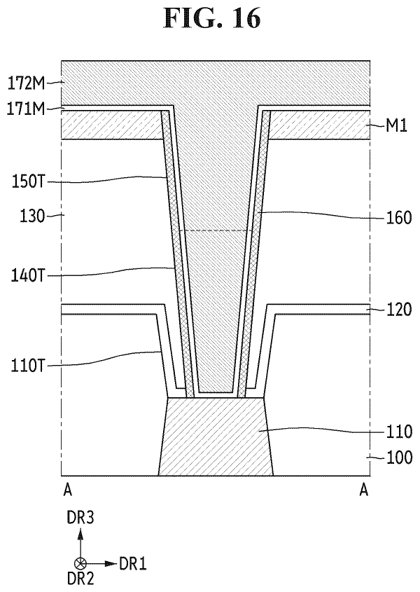

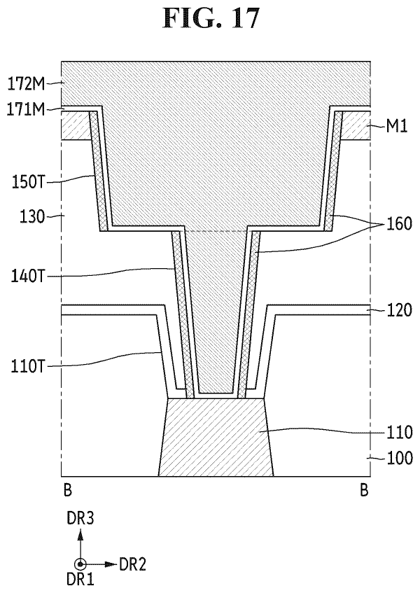

Referring to FIG. 16 and FIG. 17, a wiring barrier material layer 171M and a wiring filling material layer 172M may be sequentially formed within the via trench 140T and the upper wiring trench 150T, respectively. For example, the wiring barrier material layer 171M may be conformally formed. The wiring filling material layer 172M may fill the inside of the via trench 140T and the upper wiring trench 150T between the wiring barrier material layers 171M. For example, the wiring barrier material layer 171M and the wiring filling material layer 172M may also be formed on the upper surface of the mask pattern M1. For example, each of the wiring barrier material layer 171M and the wiring filling material layer 172M may include the same materials as the wiring barrier layer 171 and the wiring filling layer 172 shown in FIGS. 2 and 3.

Referring to FIGS. 2 and 3, a planarization process may be performed to expose the upper surface of the second interlayer insulating layer 130. After the planarization process is completed, the remaining wiring barrier material layer 171M (see FIGS. 16 and 17) and wiring filling material layer 172M (see FIGS. 16 and 17) may be defined as the wiring barrier layer 171 and the wiring filling layer 172, respectively. After the planarization process is completed, the wiring barrier layer 171 and wiring filling layer 172 remaining within the via trench 140T may be defined as the via 140. Additionally, after the planarization process is completed, the wiring barrier layer 171 and wiring filling layer 172 remaining within the upper wiring trench 150T may be defined as the upper wiring layer 150. Through this fabrication process, the semiconductor device shown in FIGS. 2 and 3 may be fabricated.

In the semiconductor device according to some embodiments of the present disclosure, the via 140 may be connected to the lower wiring layer 110 through a connection trench 110T formed on the upper surface of the lower wiring layer 110, and spacers 160 may be disposed on the sidewalls of the via 140 within the connection trench 110T. In some embodiments of the present disclosure, even if over-etching occurs toward the sidewalls of the connection trench 110T in the process of forming the via trench 140T in which the via 140 is to be arranged, the spacers 160 disposed on the sidewalls of the via 140 may additionally insulate the space between an adjacent wiring layer and the via 140. Therefore, the semiconductor device according to some embodiments of the present disclosure may improve the electrical reliability between the via 140 and the adjacent wiring layer.

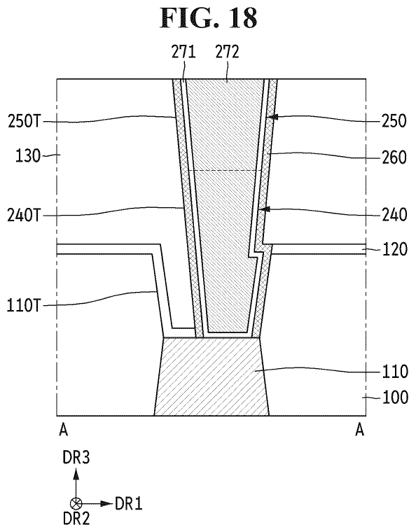

Hereinafter, a semiconductor device according to several other embodiments of the present disclosure will be described with reference to FIG. 18. The description will focus on differences from the semiconductor device shown in FIGS. 1 to 3.

FIG. 18 is a cross-sectional view for explaining a semiconductor device according to embodiments of the present disclosure.

Referring to FIG. 18, in the semiconductor device according to embodiments of the present disclosure, the sidewall of the spacer 260 in the first horizontal direction DR1 may be in contact with the first interlayer insulating layer 100 within the connection trench 110T.

For example, the connection trench 110T may include a first sidewall and a second sidewall facing each other in the first horizontal direction DR1. The via trench 240T may include a first sidewall and a second sidewall facing each other in the first horizontal direction DR1. For example, the first sidewall of the via trench 240T in the first horizontal direction DR1 may be spaced apart from the first sidewall of the connection trench 110T in the first horizontal direction DR1. For example, the etching stop layer 120 and the second interlayer insulating layer 130 may be disposed between the first sidewall of the connection trench 110T in the first horizontal direction DR1 and the first sidewall of the via trench 240T in the first horizontal direction DR1.

For example, a portion of the second sidewall of the via trench 240T in the first horizontal direction DR1 may be defined to be the same as the second sidewall of the connection trench 110T in the first horizontal direction DR1. For example, on the second sidewall of the connection trench 110T in the first horizontal direction DR1, the sidewall of the spacer 260 may be in contact with the first interlayer insulating layer 100. In another example, on the second sidewall of the connection trench 110T in the first horizontal direction DR1, the spacer 260 may have a step difference at the point where it is in contact with the etching stop layer 120. The via 240 may be disposed between the spacers 260 within the via trench 240T.

For example, an upper wiring trench 250T may be formed over the via trench 240T within the second interlayer insulating layer 130. For example, the sidewall of the upper wiring trench 250T in the first horizontal direction DR1 may have a continuous sloped profile with the sidewall of the via trench 240T in the first horizontal direction DR1. For example, the upper wiring layer 250 may be arranged within the upper wiring trench 250T. For example, the spacer 260 disposed on the sidewall of the upper wiring trench 250T in the first horizontal direction DR1 may be continuously arranged with the spacer 260 disposed on the sidewall of the via trench 240T in the first horizontal direction DR1.

For example, each of the via 240 and the upper wiring layer 250 may include the wiring barrier layer 271 and the wiring filling layer 272. The wiring barrier layer 271 may be formed on the bottom surface and sidewalls of the via 240 and on a portion of the bottom surface and sidewalls of the upper wiring layer 250. The wiring filling layer 272 may fill the space between the wiring barrier layers 271 of the via 240. Additionally, the wiring filling layer 272 may fill the space between the wiring barrier layers 271 of the upper wiring layer 250.

Hereinafter, a method for fabricating a semiconductor device according to several other embodiments of the present disclosure will be described with reference to FIGS. 18 to 23. The description will focus on differences from the method for fabricating the semiconductor device shown in FIGS. 4 to 17.

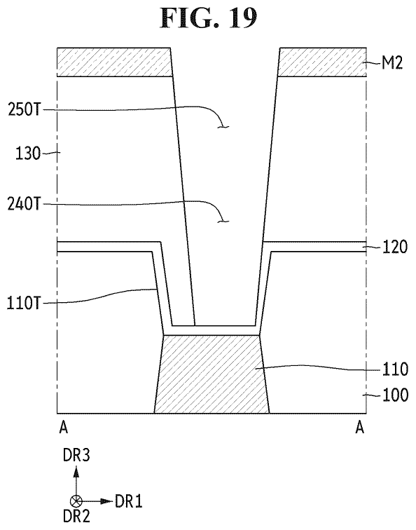

FIGS. 19 to 23 are intermediate stage diagrams for explaining a method for fabricating a semiconductor device according to embodiments of the present disclosure.

Referring to FIG. 19, after the fabrication process shown in FIGS. 4 to 7 has been performed, the via trench 240T and the upper wiring trench 250T may be formed using the mask pattern M2 provided on the upper surface of the second interlayer insulating layer 130 as a mask. For example, the via trench 240T and the upper wiring trench 250T may be formed through the same fabrication process. However, the present disclosure is not limited thereto.

For example, the via trench 240T may penetrate the second interlayer insulating layer 130 in the vertical direction DR3 over the upper surface of the lower wiring layer 110. For example, within the connection trench 110T, the etching stop layer 120 may be exposed through the bottom surface and sidewalls in the first horizontal direction DR1 of the via trench 240T. For instance, the upper wiring trench 250T may be formed over the via trench 240T.

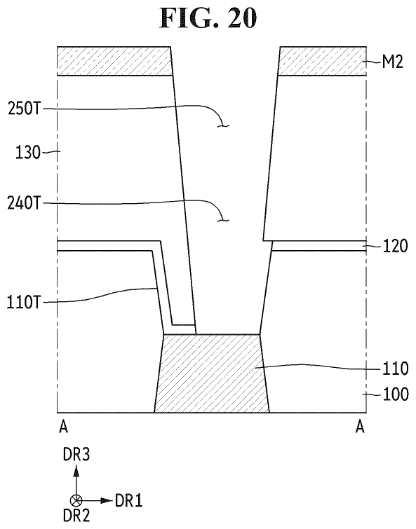

Referring to FIG. 20, the etching stop layer 120 exposed through the bottom surface and the sidewalls of the via trench 240T in the first horizontal direction DR1 may be etched. As a result, the upper surface of the lower wiring layer 110 may be exposed through the bottom surface of the via trench 240T, and the first interlayer insulating layer 100 may be exposed through the sidewalls of the via trench 240T in the first horizontal direction DR1.

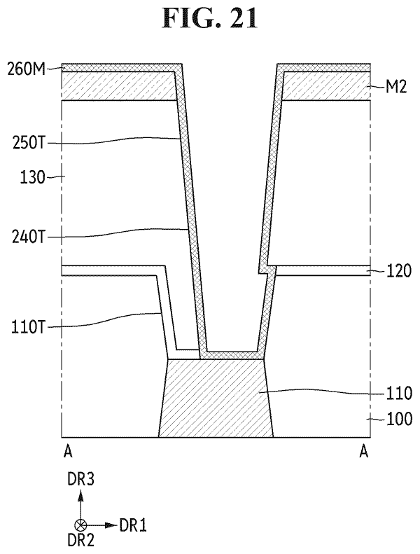

Referring to FIG. 21, the spacer material layer 260M may be formed on the sidewalls and bottom surfaces of the via trench 240T and the upper wiring trench 250T, and on the exposed surface of the mask pattern M2. For example, the spacer material layer 260M may be formed conformally. For example, the spacer material layer 260M formed on the sidewall of the connection trench 110T in the first horizontal direction DR1 may be in contact with the first interlayer insulating layer 100.

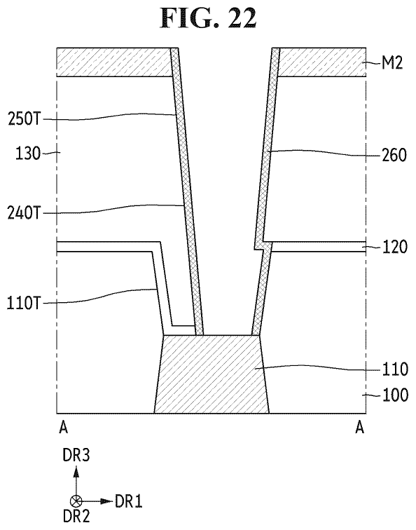

Referring to FIG. 22, for example, an etch back process may be performed to partially etch the spacer material layer 260M (see FIG. 21). For example, a portion of the spacer material layer 260M (see FIG. 21) formed on the bottom surface of the via trench 240T and on the upper surface of the mask pattern M2 may be etched. After this etching process is completed, the upper surface of the lower wiring layer 110 may be exposed through the bottom surface of the via trench 240T.

Also, after the etching process is completed, the remaining spacer material layer 260M (see FIG. 21) may be defined as a spacer 260. For example, the spacer 260 may be formed along the sidewalls of the via trench 240T. Additionally, the spacer 260 may be formed along the sidewalls of the upper wiring trench 250T. For example, the lowermost surface of the spacer 260 may be in contact with the upper surface of the lower wiring layer 110. The spacer 260 formed on the sidewall of the connection trench 110T in the first horizontal direction DR1 may be in contact with the first interlayer insulating layer 100.

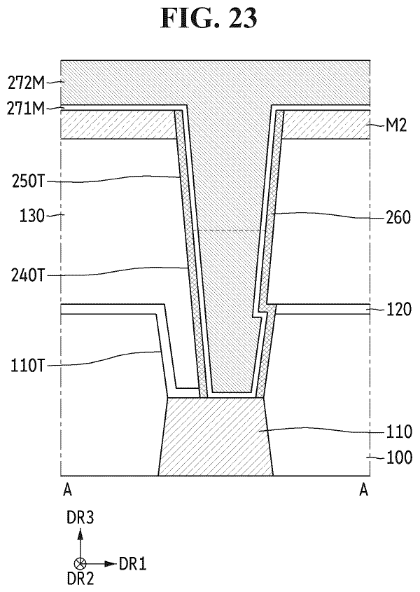

Referring to FIG. 23, a wiring barrier material layer 271M and a wiring filling material layer 272M may be sequentially formed within each of the via trench 240T and the upper wiring trench 250T. For example, the wiring barrier material layer 271M may be conformally formed. The wiring filling material layer 272M may fill the inside of the via trench 240T and the upper wiring trench 250T between the wiring barrier material layers 271M. For example, the wiring barrier material layer 271M and the wiring filling material layer 272M may also be formed on the upper surface of the mask pattern M2.

Referring to FIG. 18, a planarization process may be performed to expose the upper surface of the second interlayer insulating layer 130. After the planarization process is completed, the remaining wiring barrier material layer 271M (see FIG. 23) and wiring filling material layer 272M (see FIG. 23) may be defined as the wiring barrier layer 271 and wiring filling layer 272, respectively. After the planarization process is completed, the wiring barrier layer 271 and wiring filling layer 272 remaining within the via trench 240T may be defined as the via 240. Additionally, after the planarization process is completed, the wiring barrier layer 271 and wiring filling layer 272 remaining within the upper wiring trench 250T may be defined as the upper wiring layer 250. Through this fabrication process, the semiconductor device shown in FIG. 18 may be fabricated.

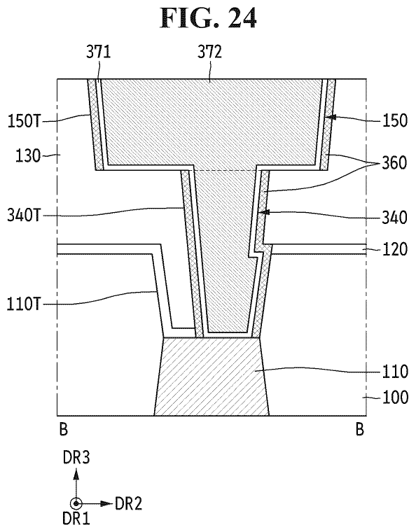

Hereinafter, a semiconductor device according to embodiments of the present disclosure will be described with reference to FIG. 24. The description will focus on differences from the semiconductor device shown in FIGS. 1 to 3.

FIG. 24 is a cross-sectional view for explaining a semiconductor device according to embodiments of the present disclosure.

Referring to FIG. 24, in the semiconductor device according to embodiments of the present disclosure, the sidewall of a spacer 360 in the second horizontal direction DR2 may be in contact with the first interlayer insulating layer 100 within the connection trench 110T.

For example, the connection trench 110T may include a first sidewall and a second sidewall facing each other in the second horizontal direction DR2. The via trench 340T may include a first sidewall and a second sidewall facing each other in the second horizontal direction DR2. For example, the first sidewall of the via trench 340T in the second horizontal direction DR2 may be spaced apart from the first sidewall of the connection trench 110T in the second horizontal direction DR2. For example, the etching stop layer 120 and the second interlayer insulating layer 130 may be disposed between the first sidewall of the connection trench 110T in the second horizontal direction DR2 and the first sidewall of the via trench 340T in the second horizontal direction DR2.

For example, a portion of the second sidewall of the via trench 340T in the second horizontal direction DR2 may be defined to be the same as the second sidewall of the connection trench 110T in the second horizontal direction DR2. For example, on the second sidewall of the connection trench 110T in the second horizontal direction DR2, the sidewall of the spacer 360 may be in contact with the first interlayer insulating layer 100. For example, on the second sidewall of the connection trench 110T in the second horizontal direction DR2, the spacer 360 may have a step difference at the point where it is in contact with the etching stop layer 120. The via 340 may be disposed between the spacers 360 within the via trench 340T.

For example, the upper wiring trench 150T may be formed over a via trench 340T within the second interlayer insulating layer 130. For example, the upper wiring layer 150 may be disposed within the upper wiring trench 150T. For example, the via 340 and the upper wiring layer 150 may each include the wiring barrier layer 371 and the wiring filling layer 372. The wiring barrier layer 371 may form the bottom surface and sidewalls of the via 340 and a portion of the bottom surface and sidewalls of the upper wiring layer 150. The wiring filling layer 372 may fill the space between the wiring barrier layers 371 of the via 340. Additionally, the wiring filling layer 372 may fill the space between the wiring barrier layers 371 of the upper wiring layer 150.

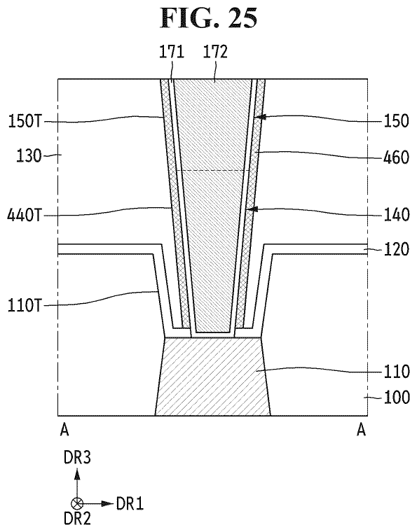

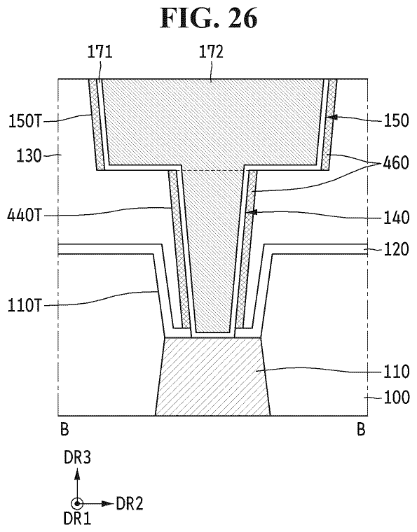

Hereinafter, a semiconductor device according to some embodiments of the present disclosure will be described with reference to FIGS. 25 and 26. The description will focus on differences from the semiconductor device shown in FIGS. 1 to 3.

FIGS. 25 and 26 are cross-sectional views for explaining a semiconductor device according to some embodiments of the present disclosure.

Referring to FIGS. 25 and 26, in the semiconductor device according to some embodiments of the present disclosure, the lowermost surface of the spacer 460 may be in contact with the etching stop layer 120.

For example, within the connection trench 110T, the lowermost surface of the spacer 460 may be spaced apart from the upper surface of the lower wiring layer 110 in the vertical direction DR3. For example, the bottom surface of the via trench 440T may have a step difference. For example, within the via trench 440T, the lowermost surface of the spacer 460 and the bottom surface of the via 140 may have a step difference. Within the via trench 440T, the lowermost surface of the spacer 460 may be formed higher than the bottom surface of the via 140.

Hereinafter, a method for fabricating a semiconductor device according to some embodiments of the present disclosure will be described with reference to FIGS. 25 to 34. The description will focus on differences from the method for fabricating the semiconductor device shown in FIGS. 4 to 17.

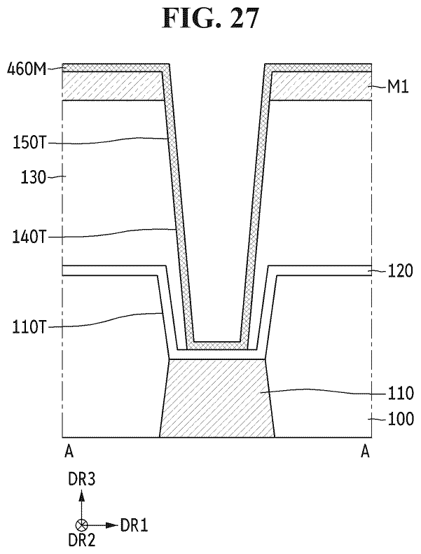

FIGS. 27 to 34 are intermediate stage diagrams for explaining a method for fabricating a semiconductor device according to some embodiments of the present disclosure.

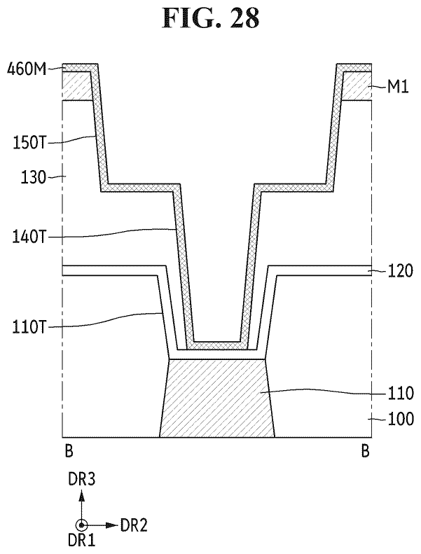

Referring to FIG. 27 and FIG. 28, after the fabrication process shown in FIGS. 4 to 9 has been performed, the spacer material layer 460M may be formed on the sidewalls and bottom surface of the via trench 140T, the sidewalls and bottom surface of the upper wiring trench 150T, and the exposed surface of the mask pattern M1. For example, the spacer material layer 460M may be formed conformally. For example, the spacer material layer 460M may include the same material as the spacer 460 shown in FIGS. 25 and 26.

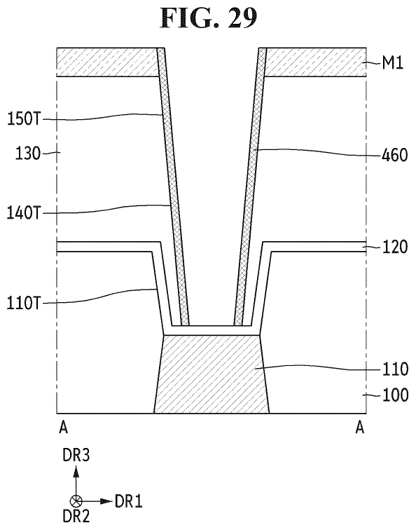

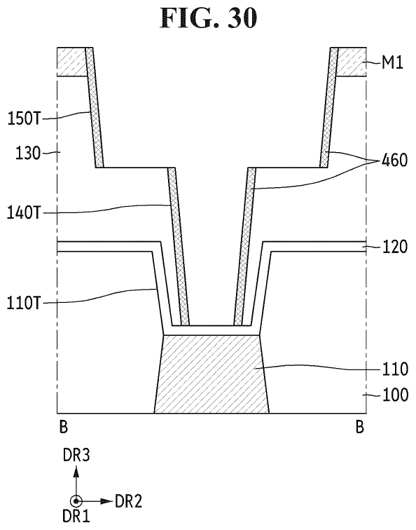

Referring to FIGS. 29 and 30, for example, an etch back process may be performed to partially etch the spacer material layer 460M (see FIGS. 27 and 28). For example, portions of the spacer material layer 460M (see FIGS. 27 and 28) formed on the bottom surface of the via trench 140T, the bottom surface of the upper wiring trench 150T, and the upper surface of the mask pattern M1 may be etched. After this etching process is completed, the upper surface of the etching stop layer 120 may be exposed through the bottom surface of the via trench 140T, and the second interlayer insulating layer 130 may be exposed through the bottom surface of the upper wiring trench 150T.

Additionally, after such an etching process is completed, the remaining spacer material layer 460M (FIGS. 27 and 28) may be defined as the spacer 460. For example, the spacer 460 may be formed along the sidewalls of the via trench 140T. Also, the spacer 460 may be formed along the sidewalls of the upper wiring trench 150T. For example, the lowermost surface of the spacer 460 may be in contact with the upper surface of the etching stop layer 120.

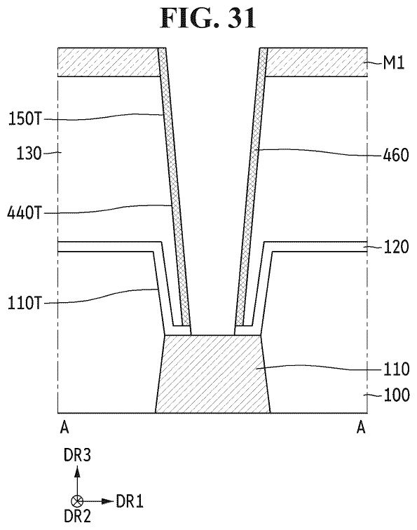

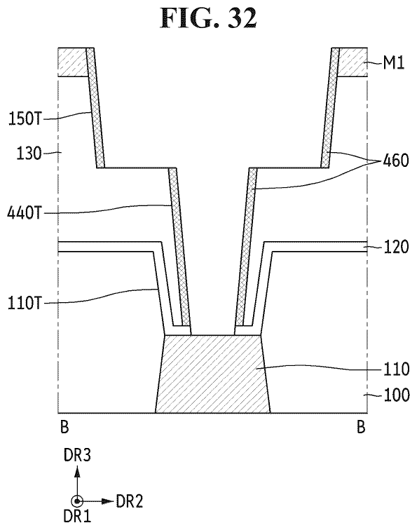

Referring to FIGS. 31 and 32, the etching stop layer 120 exposed through the bottom surface of the via trench 140T (see FIGS. 29 and 30) may be etched. After this etching process is completed, the region including the via trench 140T (see FIGS. 29 and 30) and the etched etching stop layer 120 may be defined as the via trench 440T. As a result, the upper surface of the lower wiring layer 110 may be exposed through the bottom surface of the via trench 440T.

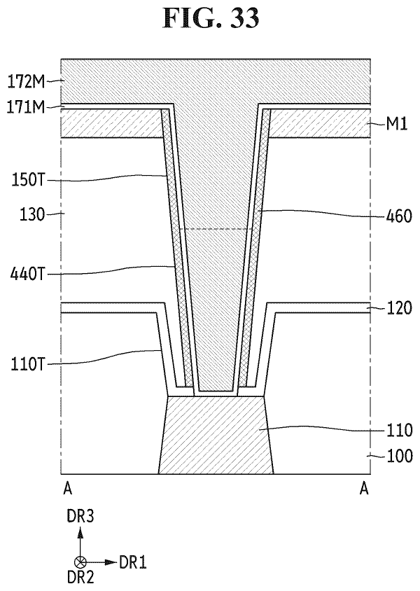

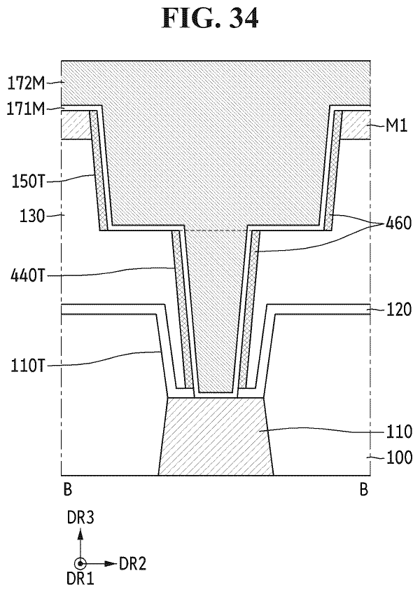

Referring to FIGS. 33 and 34, the wiring barrier material layer 171M and the wiring filling material layer 172M may be sequentially formed within each of the via trench 440T and the upper wiring trench 150T. For example, the wiring barrier material layer 171M may be formed conformally. The wiring filling layer 172M may fill the inside of the via trench 440T and the upper wiring trench 150T between the wiring barrier layers 171M. For example, the wiring barrier material layer 171M and the wiring filling material layer 172M may also be formed on the upper surface of the mask pattern M1. For example, each of the wiring barrier material layer 171M and the wiring filling material layer 172M may include the same material as the wiring barrier layer 171 and the wiring filling layer 172 shown in FIGS. 25 and 26, respectively.

Referring to FIGS. 25 and 26, a planarization process may be performed to expose the upper surface of the second interlayer insulating layer 130. After the planarization process is completed, the remaining wiring barrier material layer 171M (see FIGS. 33 and 34) and the wiring filling material layer 172M (see FIGS. 33 and 34) may be defined as the wiring barrier layer 171 and the wiring filling layer 172, respectively. After the planarization process is completed, the wiring barrier layer 171 and wiring filling layer 172 remaining within the via trench 440T may be defined as the via 140. In addition, after the planarization process is completed, the wiring barrier layer 171 and wiring filling layer 172 remaining within the upper wiring trench 150T may be defined as the upper wiring layer 150. Through this fabrication process, the semiconductor device shown in FIGS. 25 and 26 may be fabricated.

According to some embodiments of the present disclosure, there is provided a method for fabricating a semiconductor device, comprising forming a first interlayer insulating layer provided with each of a lower wiring layer and a connection trench exposing an upper surface of the lower wiring layer, forming an etching stop layer along an upper surface of the first interlayer insulating layer, and along sidewalls and a bottom surface of the connection trench, forming a second interlayer insulating layer on the etching stop layer, forming a via trench penetrating the second interlayer insulating layer in a vertical direction on the upper surface of the lower wiring layer, forming a spacer along sidewalls of the via trench, at least a portion of the spacer formed within the connection trench, and forming a via filling an inside of the via trench between the spacers, the via spaced apart from the sidewalls of the connection trench in a first horizontal direction and in a second horizontal direction perpendicular to the first horizontal direction, at least a portion of the via formed within the connection trench.

According to some embodiments of the present disclosure, there is provided a method for fabricating a semiconductor device, wherein forming the via trench further comprises forming an upper wiring trench over the via trench, and wherein a width of the upper wiring trench in the second horizontal direction is greater than a width of the via trench in the second horizontal direction.

According to some embodiments of the present disclosure, there is provided a method for fabricating a semiconductor device, wherein forming the spacer further comprises forming the spacer along a sidewall of the upper wiring trench.

According to some embodiments of the present disclosure, there is provided a method for fabricating a semiconductor device, wherein forming the via trench further comprises the via trench penetrating the second interlayer insulating layer and the etching stop layer in the vertical direction to expose the upper surface of the lower wiring layer.

According to some embodiments of the present disclosure, there is provided a method for fabricating a semiconductor device, further comprising before forming the via, etching the etching stop layer exposed between the spacers within the via trench to expose the upper surface of the lower wiring layer.

While the embodiments of the present disclosure have been described above with reference to the accompanying drawings, it will be understood that the present disclosure is not limited to these embodiments, and may be implemented in various other forms. Those skilled in the art to which the present disclosure pertains will understand that the present disclosure may be implemented in other specific forms without changing the technical idea or essential features. Accordingly, the embodiments described above should be understood to be exemplary in all respects and not restrictive.

What is claimed is:

1. A semiconductor device comprising:
a first interlayer insulating layer;
a lower wiring layer disposed in the first interlayer insulating layer;
a connection trench formed on an upper surface of the lower wiring layer within the first interlayer insulating layer, the connection trench extending in a vertical direction from the upper surface of the lower wiring layer to an upper surface of the first interlayer insulating layer;
an etching stop layer disposed along the upper surface of the first interlayer insulating layer, and sidewalls and a bottom surface of the connection trench;
a second interlayer insulating layer disposed on an upper surface of the etching stop layer;
a via disposed on the upper surface of the lower wiring layer within the second interlayer insulating layer, at least a portion of the via disposed within the connection trench, the via spaced apart from the sidewalls of the connection trench in a first horizontal direction and in a second horizontal direction perpendicular to the first horizontal direction; and
a spacer surrounding sidewalls of the via, and at least a portion of the spacer disposed within the connection trench.

2. The semiconductor device of claim 1, wherein at least a portion of the etching stop layer is disposed between a first sidewall of the connection trench in the first horizontal direction and the spacer.

3. The semiconductor device of claim 2, wherein the spacer is in contact with the first interlayer insulating layer on a second sidewall of the connection trench in the first horizontal direction.

4. The semiconductor device of claim 1, wherein at least a portion of the etching stop layer is disposed between a first sidewall of the connection trench in the second horizontal direction and the spacer.

5. The semiconductor device of claim 4, wherein the spacer is in contact with the first interlayer insulating layer on a second sidewall of the connection trench in the second horizontal direction.

6. The semiconductor device of claim 1,
wherein at least a portion of the second interlayer insulating layer is disposed between the etching stop layer and the spacer within the connection trench.

7. The semiconductor device of claim 1, further comprising:
an upper wiring layer being in contact with an upper surface of the via within the second interlayer insulating layer, a width of a bottom surface of the upper wiring layer in the second horizontal direction greater than a width of the upper surface of the via in the second horizontal direction.

8. The semiconductor device of claim 7, wherein the spacer is disposed on each sidewall of the upper wiring layer in the first and second horizontal directions.

9. The semiconductor device of claim 7, wherein each of the via and the upper wiring layer comprises:
a wiring barrier layer forming a bottom surface and the sidewalls of the via, and a portion of the bottom surface and sidewalls of the upper wiring layer, and
a wiring filling layer filling a space between the wiring barrier layers, and
wherein an upper surface of the wiring filling layer of the via is in contact with a bottom surface of the wiring filling layer of the upper wiring layer.

10. The semiconductor device of claim 7, wherein the sidewall of the via in the first horizontal direction has a continuous sloped profile with a sidewall of the upper wiring layer in the first horizontal direction.

11. The semiconductor device of claim 1, wherein a material of the spacer is different from a material of the etching stop layer.

12. The semiconductor device of claim 1, wherein a lowermost surface of the spacer is in contact with the upper surface of the lower wiring layer.

13. A semiconductor device comprising:
a first interlayer insulating layer,
a lower wiring layer disposed in the first interlayer insulating layer;
a connection trench formed on an upper surface of the lower wiring layer within the first interlayer insulating layer, the connection trench extending in a vertical direction from the upper surface of the lower wiring layer to an upper surface of the first interlayer insulating layer;
a second interlayer insulating layer disposed on the upper surface of the first interlayer insulating layer, and at least a portion of the second interlayer insulating layer disposed within the connection trench;
a via disposed on the upper surface of the lower wiring layer within the second interlayer insulating layer, at least a portion of the via disposed within the connection trench. the via spaced apart from sidewalls of the connection trench in a first horizontal direction and in a second horizontal direction perpendicular to the first horizontal direction,
an upper wiring layer being in contact with an upper surface of the via within the second interlayer insulating layer, and
a spacer surrounding each of sidewalls of the via and sidewalls of the upper wiring layer, at least a portion of the spacer disposed within the connection trench, 14. The semiconductor device of claim 13, further comprising:
an etching stop layer disposed between the first interlayer insulating layer and the second interlayer insulating layer, the etching stop layer disposed along the sidewall and a bottom surface of the connection trench, the etching stop layer disposed between the first interlayer insulating layer and the spacer within the connection trench.

15. The semiconductor device of claim 14, wherein at least a portion of the second interlayer insulating layer is disposed between the etching stop layer and the spacer within the connection trench.

16. The semiconductor device of claim 14, wherein a lowermost surface of the spacer is in contact with the etching stop layer.

17. The semiconductor device of claim 13, wherein an uppermost surface of the spacer is formed on a same plane as a plane of an upper surface of the upper wiring layer.

18. The semiconductor device of claim 13, wherein a width of a bottom surface of the upper wiring layer in the first horizontal direction is same as a width of the upper surface of the via in the first horizontal direction, and
wherein a width of the bottom surface of the upper wiring layer in the second horizontal direction is greater than a width of the upper surface of the via in the second horizontal direction.

19. The semiconductor device of claim 13, wherein a bottom surface of the upper wiring layer is in contact with the second interlayer insulating layer on the sidewall of the via in the second horizontal direction, 20. A semiconductor device comprising:
a first interlayer insulating layer;
a lower wiring layer disposed in the first interlayer insulating layer;
a connection trench formed on an upper surface of the lower wiring layer within the first interlayer insulating layer, the connection trench extending in a vertical direction from the upper surface of the lower wiring layer to an upper surface of the first interlayer insulating layer;
an etching stop layer disposed along the upper surface of the first interlayer insulating layer, and sidewalls and a bottom surface of the connection trench;
a second interlayer insulating layer disposed on an upper surface of the etching stop layer, at least a portion of the second interlayer insulating layer disposed within the connection trench;
a via disposed on the upper surface of the lower wiring layer within the second interlayer insulating layer, at least a portion of the via disposed within the connection trench, the via spaced apart from the sidewalls of the connection trench in a first horizontal direction and in a second horizontal direction perpendicular to the first horizontal direction;
an upper wiring layer being in contact with an upper surface of the via within the second interlayer insulating layer, and having a width of a bottom surface in the second horizontal direction greater than a width of the upper surface of the via in the second horizontal direction, and
a spacer surrounding each of sidewalls of the via and sidewalls of the upper wiring layer, at least a portion of the spacer disposed within the connection trench, an uppermost surface of the spacer formed on a same plane as a plane of an upper surface of the upper wiring layer, a lowermost surface of the spacer being in contact with the upper surface of the lower wiring layer,
wherein at least a portion of the etching stop layer is disposed between the sidewall of the connection trench in the first horizontal direction and the spacer, and
wherein at least a portion of the etching stop layer is disposed between the sidewall of the connection trench in the second horizontal direction and the spacer.
